(19) United States
(12) Patent Application Publication
(10) Pub. No.: US 2009/0224307 A1
(43) Pub. Date: Sep. 10, 2009

(54) Semiconductor Device and Method of Fabricating the Same

(75) Inventors: Byung In Lee, Icheon-Si (KR); Young Bok Lee, Icheon-Si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-shi (KR)

(21) Appl. No.: 12/398,817

(22) Filed: Mar. 5, 2009

(30) Foreign Application Priority Data
Mar. 10, 2008 (KR) 10-2008-0021951

(51) Int. Cl. H01L 29/788; H01L 21/4763

(52) U.S. Cl. 257/316; 438/594; 257/E29.3; 257/E21.495

(57) ABSTRACT

A semiconductor device and method of fabricating the same. In an aspect of the inventive method, a tunnel insulating layer, a first conductive layer, a dielectric layer, a second conductive layer, and a gate electrode layer are sequentially stacked over a semiconductor substrate. The gate electrode layer is patterned in order to expose the second conductive layer. A passivation layer is formed on sidewalls of the gate electrode layer. Gate patterns are formed by etching the exposed second conductive layer, the dielectric layer, and the first conductive layer using the passivation layer as a mask.

### CROSS-REFERENCES TO RELATED APPLICATION

Priority to Korean patent application number 10-2008-0021951 filed on Mar. 10, 2008, the entire disclosure of which is incorporated by reference herein, is claimed.

### BACKGROUND OF THE INVENTION

The invention relates generally to a semiconductor device and method of fabricating the same and, more particularly, to a semiconductor device and method of fabricating the same, that is capable of forming gate patterns.

In general, in a flash memory semiconductor device, a gate pattern is formed by patterning a conductive layer for a floating gate, a dielectric layer, a conductive layer for a control gate, and a gate electrode.

FIG. 1 is a sectional view of a semiconductor device for forming gate patterns of a prior art flash memory device.

Referring to FIG. 1, a tunnel insulating layer 11, a conductive layer 12 for a floating gate, a dielectric layer 13, a conductive layer 14 for a control gate, a gate electrode layer 15, and a hard mask layer 16 are sequentially stacked over a semiconductor substrate 10. The hard mask layer 16 is patterned. The gate electrode layer 15, the conductive layer 14, the dielectric layer 13, the conductive layer 12, and the tunnel insulating layer 11 are then sequentially patterned using an etch process employing the patterned hard mask layer 16, thus forming gate patterns.

In general, in a case in which the gate electrode layer is formed from a tungsten silicide (WSiₓ) in semiconductor devices of 50 nm or less, resistance (Rs) of a word line increases because the tungsten silicide (WSiₓ) layer itself has a high resistivity. Thus, the program speed and the read speed are significantly lowered. To solve this problem, the thickness of the tungsten silicide (WSiₓ) layer must be increased, but this may complicate a process of patterning word lines and cause the formation of voids within isolation layers, thus electrically isolating the word lines. Research has been done on a method of forming the gate electrode layer using a tungsten (W) layer having resistivity lower than that of the tungsten silicide (WSiₓ) layer.

However, use of a tungsten layer seriously limits subsequent processes because it is easily oxidized by thermal processes and easily eroded or oxidized by cleaning solutions used in cleaning process.

Further, as the degree of integration of semiconductor devices gradually increases, the critical dimension of gate patterns gradually decreases, resulting in a reduced effective channel length. In order to secure an effective channel length, after the gate electrode layer 15 is patterned, error has to be reduced by correcting an etch mask. Next, even when the conductive layer 12 for a floating gate is patterned, an accurate gate pattern etch process must be performed by correcting an etch mask in order to secure the effective channel length of the device. This correction process of the etch mask increases turnaround time and expense.

Further, in order to secure an optimal critical dimension of a floating gate, the critical dimension of a control gate must be increased. However, this generates a word line bridge phenomenon or reduces interference margin between cells, thus posing many difficulties in the fabrication process.

### BRIEF SUMMARY OF THE INVENTION

The invention is directed to a semiconductor device and method of fabricating the same, wherein, in a process of forming gate patterns of the semiconductor device, a gate electrode layer is patterned and exposed surfaces of the gate electrode layer, i.e., sidewalls of the gate electrode layer, are then surrounded with a passivation layer, thus preventing the gate electrode layer from being oxidized at the time of subsequent thermal, cleaning, and etch processes.

A semiconductor device according to an aspect of the invention comprises a plurality of gate patterns, each comprising a sequentially stacked tunnel insulating layer, conductive layer for a floating gate, dielectric layer, conductive layer for a control gate, and gate electrode layer over a semiconductor substrate, and a passivation layer formed on sidewalls of the gate electrode layer.

The passivation layer preferably has a dual structure, comprising a nitride layer, highly preferably a nitride layer and an oxide layer. The passivation layer comprises a nitride layer.

A critical dimension of the gate electrode layer preferably is smaller than a critical dimension of the conductive layer for a floating gate. The gate electrode layer preferably comprises tungsten (W).

A hard mask patter preferably is further formed on the gate electrode layer. An anti-diffusion layer preferably is further formed between the gate electrode layer and the conductive layer for a control gate.

A method of fabricating a semiconductor device according to another aspect of the invention comprises sequentially stacking a tunnel insulating layer, a first conductive layer, a dielectric layer, a second conductive layer, and a gate electrode layer over a semiconductor substrate, patterning the gate electrode layer to expose the second conductive layer, forming a passivation layer on sidewalls of the gate electrode layer, and forming gate patterns by etching the exposed second conductive layer, the dielectric layer, and the first conductive layer using the passivation layer as a mask.

After the gate electrode layer is formed, a hard mask layer preferably is formed on the gate electrode layer, preferably by sequentially stacking an SiON layer, a TEOS oxide layer, and an amorphous carbon layer.

Patterning of the gate electrode layer preferably comprises etching the gate electrode layer such that a critical dimension of the gate electrode layer is smaller than a critical dimension of the gate patterns. The second conductive layer and the first conductive layer preferably are patterned such that a critical dimension of either the second conductive layer or the first conductive layer is greater than a critical dimension of the gate electrode layer.

The passivation layer preferably has a dual structure comprising a nitride layer and an oxide layer. The dielectric layer preferably comprises a first oxide layer, a nitride layer, and a second oxide layer. A second oxide layer preferably is thinner than the first oxide layer.

The passivation layer preferably is formed using a thermal treatment process. The thermal treatment process preferably is performed using NH₃ gas. The thermal treatment process preferably is performed in a temperature range of 800 degrees Celsius to 1000 degrees Celsius. The thermal treatment process preferably is performed at 900 degrees Celsius for 15 seconds to 20 seconds.

### BRIEF DESCRIPTION OF THE DRAWINGS

FIG. 1 is a sectional view of a semiconductor device for forming gate patterns of the device according to the prior art;

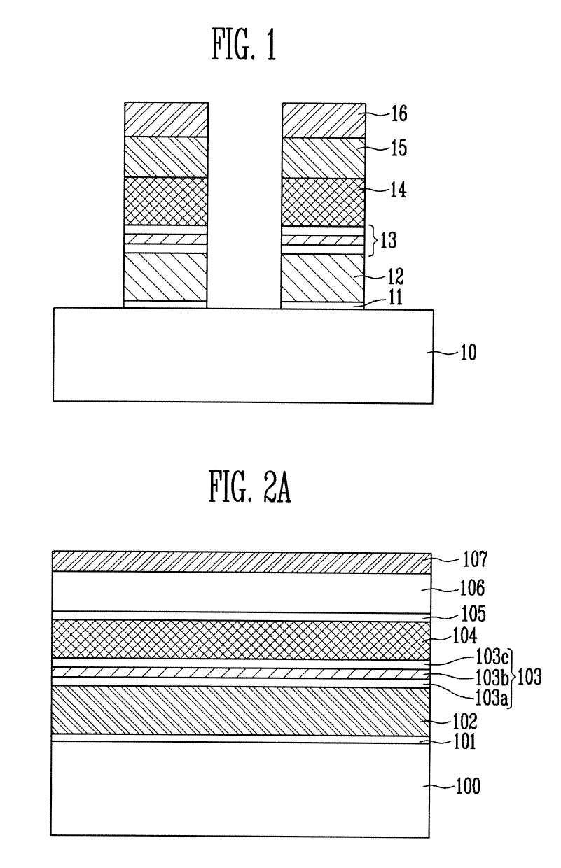

FIGS. 2A to 2C are sectional views illustrating a method of fabricating a semiconductor device according to a first embodiment of the invention;

FIGS. 3A and 3B sectional views illustrating a method of fabricating a semiconductor device according to a second embodiment of the invention; and

FIGS. 4A and 4B are graphs showing resistance values of a passivation layer under process conditions of a thermal treatment process employing NH₃ gas.

### DESCRIPTION OF SPECIFIC EMBODIMENTS

The invention is described below in detail in connection with specific embodiments with reference to the accompanying drawings. The illustrated embodiments are provided to complete the disclosure of the invention and to allow those having ordinary skill in the art to understand the scope of the invention. When it is said that any part, such as a layer or film, is positioned on another part, it means the part is directly on the other part or above the other part with at least one intermediate part. To clarify multiple layers and regions, thicknesses of layers are enlarged in the drawings.

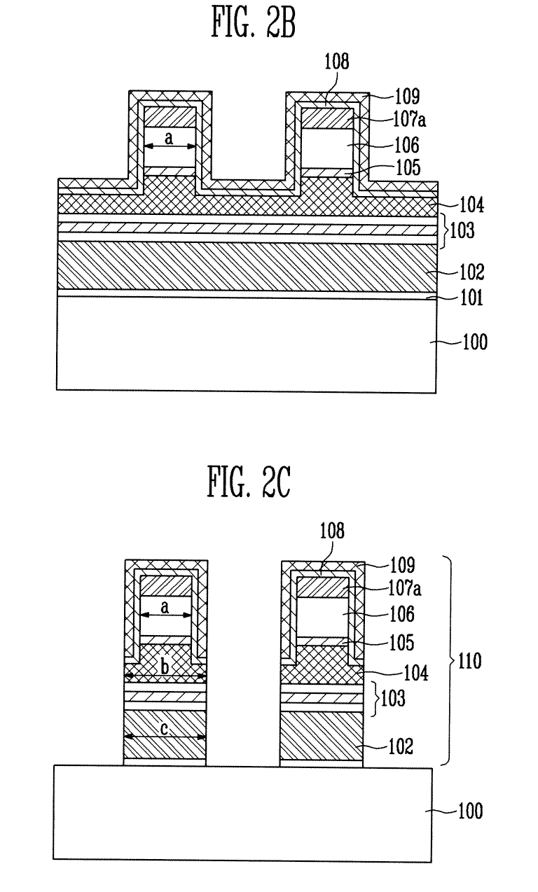

FIGS. 2A to 2C are sectional views illustrating a method of fabricating a semiconductor device according to a first embodiment of the invention.

Referring to FIG. 2A, a tunnel insulating layer 101, a conductive layer 102 for a floating gate, a dielectric layer 103, a conductive layer 104 for a control gate, a gate electrode layer 106, and a hard mask layer 107 are sequentially stacked over a semiconductor substrate 100.

The conductive layer 102 for a floating gate and the conductive layer 104 for a control gate are preferably each formed from a polysilicon layer. The dielectric layer 103 preferably has an ONO structure comprising a first oxide layer 103a, a nitride layer 103b, and a second oxide layer 103c. The gate electrode layer 106 preferably is formed from a tungsten (W) layer.

Conductive layer 102 for a floating gate preferably has a dual layer, including an amorphous polysilicon layer not including an impurity and a polysilicon layer including an impurity.

An anti-diffusion layer 105 preferably is formed between the formation of the gate electrode layer 106 and the formation of the conductive layer 104 for a control gate. The anti-diffusion layer 105 preferably is formed from a WN layer.

The hard mask layer 107 preferably is formed by sequentially stacking an SiON layer, a TEOS oxide layer, and an amorphous carbon layer.

Referring to FIG. 2B, after a photoresist pattern is formed on the hard mask layer 107, an etch process employing the photoresist pattern is performed, to pattern the hard mask layer 107.

Next, the gate electrode layer 106, the anti-diffusion layer 105, and the conductive layer 104 for a control gate are etched by performing an etch process using a patterned hard mask layer 107a as an etch mask, thus forming primary gate patterns. At this time, the etch process preferably is performed to etch up to a central potion of the conductive layer 104 for a control gate.

The critical dimension “a” of the patterned gate electrode layer 106 preferably is smaller than a critical dimension of gate patterns to be formed subsequently. The critical dimension “a” of the gate electrode layer 106 preferably is formed to be 10 nm smaller than the critical dimension of the gate patterns.

A first passivation layer 108 is formed over the primary gate patterns and the conductive layer 104 for a control gate. The first passivation layer 108 preferably comprises a nitride layer.

A second passivation layer 109 is formed over the entire surface including the first passivation layer 108.

The second passivation layer 109 preferably comprises an oxide layer.

The first and second passivation layers 108 and 109 function to prevent abnormal oxidization by protecting the sidewalls of the gate electrode layer 106, which are exposed at the time of a subsequent process. Further, in order to prevent the sidewalls of the gate electrode layer 106 from being etched at the time of a subsequent process of etching the dielectric layer 103, the first and second passivation layers 108 and 109 may have a dual structure of a nitride layer and an oxide layer. The second passivation layer 109 preferably is thicker than the second oxide layer 103c of the dielectric layer 103.

Referring to FIG. 2C, the first and second passivation layers 108 and 109 formed over the conductive layer 104, the conductive layer 104, the dielectric layer 103, the conductive layer 102, and the tunnel insulating layer 101 are etched by performing an etch process, thus forming gate patterns 110.

At this time, the conductive layer 104 and the conductive layer 102 preferably are etched such that a critical dimension “b” of the conductive layer 104 or a critical dimension “c” of the conductive layer 102 is greater than the critical dimension “a” of the gate electrode layer 106. This is for the purpose of securing the effective channel length of the device.

The critical dimension “c” of the conductive layer 102 for a floating gate may be controlled by increasing a deposition thickness of the first and second passivation layers 108 and 109.

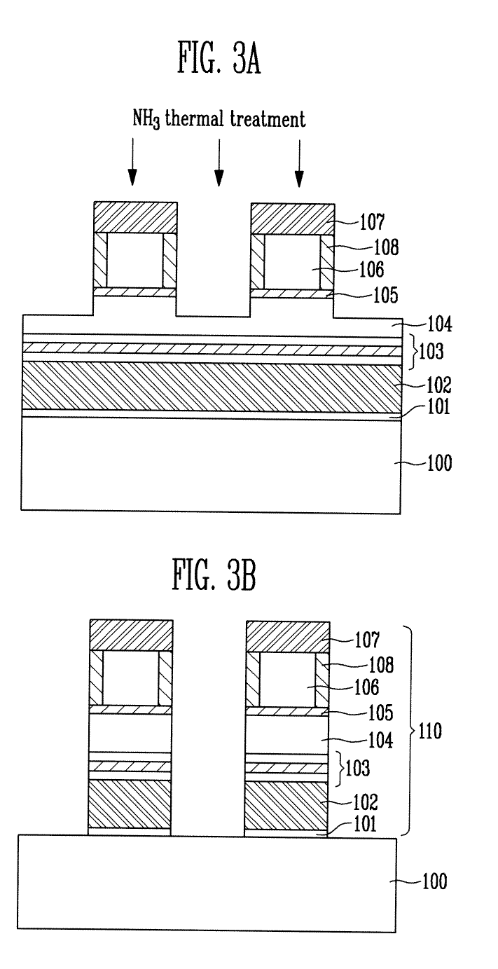

FIGS. 3A and 3B sectional views illustrating a method of fabricating a semiconductor device according to a second embodiment of the invention.

The second embodiment of the invention is identical to the first embodiment up to the process shown in FIG. 2A and, therefore, a detailed description of the same portion is omitted for simplicity.

Referring to FIG. 3A, after a photoresist pattern is formed on a hard mask layer 107, an etch process employing the photoresist pattern is performed. That is, the hard mask layer 107 is patterned.

Next, a gate electrode layer 106, an anti-diffusion layer 105, and a conductive layer 104 for a control gate are etched by performing an etch process using a patterned hard mask layer 107a as an etch mask, thus forming primary gate patterns. At this time, the etch process preferably is performed to etch a central portion of the conductive layer 104.

The sidewalls of the gate electrode layer 106 are transformed using a thermal treatment process in order to form a passivation layer 108. The passivation layer 108 preferably comprises a WNₓ layer. The thermal treatment process preferably is performed using NH₃ gas.

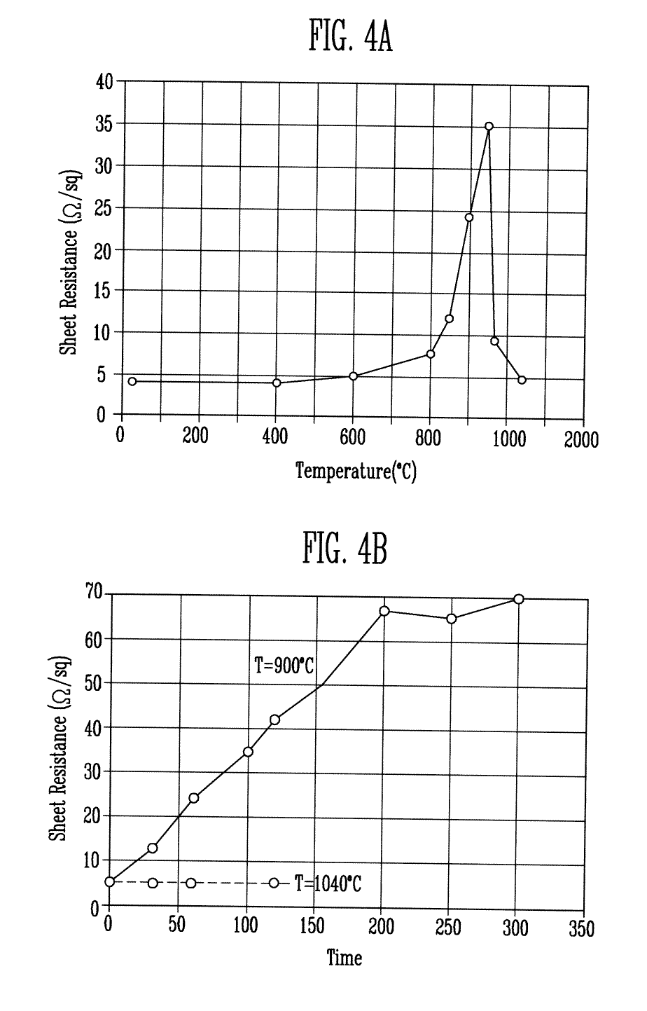

FIGS. 4A and 4B are graphs showing resistance values of the passivation layer 108 under process conditions of a thermal treatment process employing NH₃ gas. From the graphs, it can be seen that, when the thermal treatment process is performed in a temperature range of 800 degrees Celsius to 1000 degrees Celsius, the resistance value is high. More preferably, the thermal treatment process may be performed at 900 degrees Celsius. Further, in the case in which the thermal treatment process is performed at 900 degrees Celsius, when the thermal treatment process is performed for a time period of 15 seconds to 20 seconds, the resistance value is high. Accordingly, the thermal treatment process of the invention is preferably performed at 900 degrees Celsius for 15 seconds to 20 seconds.

At this time, the exposed surface of the conductive layer 104 for a control gate may be also transformed into a SiₓNₓ layer due to the thermal treatment process. The transformed layer is removed when a subsequent process of etching the dielectric layer 103 is performed.

Referring to FIG. 3B, the conductive layer 104 for a control gate, the dielectric layer 103, the conductive layer 102 for a floating gate, and the tunnel insulating layer 101 are etched by performing an etch process, thus forming gate patterns 110. The sidewalls of the gate electrode layer 106 are protected by the passivation layer 108 at the time of the etch process, so abnormal oxidization can be prevented.

According to an embodiment of the invention, in a process of forming gate patterns of a semiconductor device, a gate electrode layer is patterned and exposed surfaces of the gate electrode layer, that is, sidewalls of the gate electrode layer are then surrounded with a passivation layer. Accordingly, the gate electrode layer can be prevented from being oxidized at the time of subsequent thermal, cleaning and etch processes.

Further, gate patterns are formed such that the critical dimensions of a control gate and a floating gate are greater than the critical dimension of the gate electrode layer. Accordingly, an effective channel length of a device can be secured easily.

The embodiments disclosed herein have been proposed to allow a person skilled in the art to easily implement the invention, and the person skilled in the part may implement the invention by a combination of these embodiments. Therefore, the scope of the invention is not limited by or to the embodiments as described above, and should be construed to be defined only by the appended claims and their equivalents.

What is claimed is:

1. A semiconductor device, comprising:
a plurality of gate patterns each comprising a tunnel insulating layer, a conductive layer for a floating gate, a dielectric layer, a conductive layer for a control gate, and a gate electrode layer sequentially stacked over a semiconductor substrate, the gate electrode layer defining sidewalls; and
a passivation layer formed on the sidewalls of the gate electrode layer.

2. The semiconductor device of claim 1, wherein the passivation layer has a dual structure, comprising a nitride layer.

3. The semiconductor device of claim 2, wherein the passivation layer comprises a nitride layer and an oxide layer.

4. The semiconductor device of claim 1, wherein the passivation layer comprises a nitride layer.

5. The semiconductor device of claim 1, wherein a critical dimension of the gate electrode layer is smaller than a critical dimension of the conductive layer for a floating gate.

6. The semiconductor device of claim 1, wherein the gate electrode layer comprises tungsten (W).

7. The semiconductor device of claim 1, further comprising a hard mask pattern formed on the gate electrode layer.

8. The semiconductor device of claim 1, further comprising an anti-diffusion layer formed between the gate electrode layer and the conductive layer for a control gate.

9. A method of fabricating a semiconductor device, comprising:
sequentially stacking a tunnel insulating layer, a first conductive layer, a dielectric layer, a second conductive layer, and a gate electrode layer over a semiconductor substrate;
patterning the gate electrode layer in order to expose at least a portion of the second conductive layer;
forming a passivation layer on sidewalls of the gate electrode layer; and
forming gate patterns by etching the exposed second conductive layer, the dielectric layer, and the first conductive layer using the passivation layer as a mask.

10. The method of claim 9, further comprising, after forming the gate electrode layer, forming a hard mask layer on the gate electrode layer.

11. The method of claim 10, wherein the hard mask layer is formed by sequentially stacking an SiON layer, a TEOS oxide layer, and an amorphous carbon layer.

12. The method of claim 9, wherein a critical dimension of the gate electrode layer is smaller than a critical dimension of the gate patterns.

13. The method of claim 9, wherein a critical dimension of either the patterned second conductive layer or the first conductive layer is greater than a critical dimension of the gate electrode layer.

14. The method of claim 9, wherein the passivation layer has a dual structure comprising a nitride layer and an oxide layer.

15. The method of claim 14, wherein the dielectric layer comprises a first oxide layer, a nitride layer, and a second oxide layer.

16. The method of claim 15, wherein the second oxide layer is thinner than the first oxide layer.

17. The method of claim 9, wherein the passivation layer is formed by a thermal treatment process.

18. The method of claim 17, wherein the thermal treatment process is performed using NH₃ gas.

19. The method of claim 17, wherein the thermal treatment process is performed in a temperature range of 800 degrees Celsius to 1000 degrees Celsius.

20. The method of claim 17, wherein the thermal treatment process is performed at 900 degrees Celsius for 15 seconds to 20 seconds.

21. A method of fabricating a semiconductor device, comprising:
sequentially stacking a tunnel insulating layer, a first conductive layer, a dielectric layer, a second conductive layer, a gate electrode layer, and a hard mask layer over a semiconductor substrate, the gate electrode layer defining sidewalls;
patterning the hard mask layer and the gate electrode layer to expose the second conductive layer;
forming a passivation layer on the sidewalls of the gate electrode layer by performing a thermal treatment process; and
forming gate patterns by etching the exposed second conductive layer, the dielectric layer, and the first conductive layer, wherein a critical dimension of either the second conductive layer or the first conductive layer is greater than a critical dimension of the gate electrode layer.

22. The method of claim 21, wherein the thermal treatment process is performed at 900 degrees Celsius using NH₃ gas for 15 seconds to 20 seconds.
